(19) United States
(12) Patent Application Publication
(10) Pub. No.: US 2009/0173376 A1
(43) Pub. Date: Jul. 9, 2009

(54) SOLAR COLLECTOR DESICCANT SYSTEM

(75) Inventors: Mark Spencer, San Jose, CA (US); Stephen Askins, Ledyard, CT (US)

Correspondence Address: THE MUELLER LAW OFFICE, P.C., 12951 Harwick Lane, San Diego, CA, 92130, US

(73) Assignee: SOLFOCUS, INC., Mountain View, CA (US)

(21) Appl. No.: 12/104,415

(22) Filed: Apr. 16, 2008

Related U.S. Application Data
(60) Provisional application No. 61/019,586, filed on Jan. 7, 2008.

(51) Int. Cl. F24J 2/46; B01D 53/04; H01L 31/058

(52) U.S. Cl. 136/248; 96/146; 126/569; 95/148

(57) ABSTRACT

The present invention is a desiccant system for controlling moisture in a solar collector. The desiccant system has a desiccant bed enclosed within a housing, and is thermally coupled to the solar collector as well as being fluidly coupled to it through an orifice. Waste heat from the solar collector is conducted to the desiccant system and is used to regenerate the desiccant bed. The desiccant system includes moisture barriers which cause moisture from the desiccant to preferentially be released to the external environment rather than entering the solar collector.

### RELATED APPLICATIONS

This application claims priority to U.S. Provisional Patent Application Ser. No. 61/019,586 filed on Jan. 7, 2008 entitled “Solar Collector Desiccant System,” which is hereby incorporated by reference as if set forth in full in this application for all purposes.

### BACKGROUND OF THE INVENTION

As the demand for solar energy continues to increase as a source of renewable energy, solar collectors must be designed to operate under the wide range of climate conditions which may be encountered worldwide. In one aspect of environmental conditions, solar collectors must be able to withstand exposure to moisture, such as rain, high humidity in tropical zones, and condensation in cold climates.

Solar collectors can be generally categorized into two types, flat panel technology and solar concentrators. Flat panels are large arrays of photovoltaic cells in which solar radiation impinges directly on the cells. In contrast, solar concentrators utilize optical elements such as lenses and mirrors to concentrate light onto a much smaller area of photovoltaic cell. Solar concentrators have a high efficiency in converting solar energy to electricity due to the focused intensity of sunlight, and they also reduce cost due to the decreased amount of costly photovoltaic cells required.

While flat panels incorporate very little or no air space within their systems, solar concentrators may contain a significant amount of air space due to the presence of optical elements which are used to concentrate light. As a solar concentrator module heats and cools over the cycle of a day, moisture-laden air can be drawn into the air space of the concentrator. Moisture which forms on an optical component can affect the transmissive, reflective, and refractive characteristics of the component. Because solar concentrator systems focus light onto a small area, even a slight deviation in optical accuracy can greatly affect the efficiency of the system. Moisture within a solar collector can result in other problems, such as diffusion into semiconductor devices, degradation of certain coatings, and corrosion of electrical leads and other metal parts. Moisture and humidity can have an impact on solar collectors in average climates, but can pose even more of a problem in tropical climates or during inclement weather conditions.

Previous approaches for controlling or limiting the entry of moisture into a solar collector include utilizing open-air vents, sealing modules, employing desiccants, and installing filters. However, there continues to be a need for improved moisture control systems which can function more efficiently, require little maintenance, be cost-effective, and have minimal impact on overall solar array installation.

### SUMMARY OF THE INVENTION

The present invention is a desiccant system for controlling moisture in a solar collector. The desiccant system has a desiccant bed enclosed within a housing, and is thermally coupled to the solar collector as well as being fluidly coupled to it through an orifice. Waste heat from the solar collector is conducted to the desiccant system and is used to regenerate the desiccant bed. The desiccant system includes moisture barriers which cause moisture from the desiccant to preferentially be released to the external environment rather than entering the solar collector. The desiccant system may be positioned underneath the solar collector, and may optionally include features to increase the surface area for transferring heat to the desiccant bed.

### BRIEF DESCRIPTION OF THE DRAWINGS

Reference now will be made in detail to embodiments of the disclosed invention, one or more examples of which are illustrated in the accompanying drawings wherein:

FIG. 1 is a cross-sectional view of an exemplary solar collector desiccant system;

FIG. 2 depicts a cross-sectional view of an alternative embodiment of the present invention;

FIG. 3 shows a cross-sectional view of an embodiment of a desiccant system for a solar collector array;

FIG. 4 illustrates a cross-sectional view of a solar collector with a non-planar heat sink; and

FIG. 5 shows an exemplary desiccant system with fins.

### DETAILED DESCRIPTION OF THE EMBODIMENTS

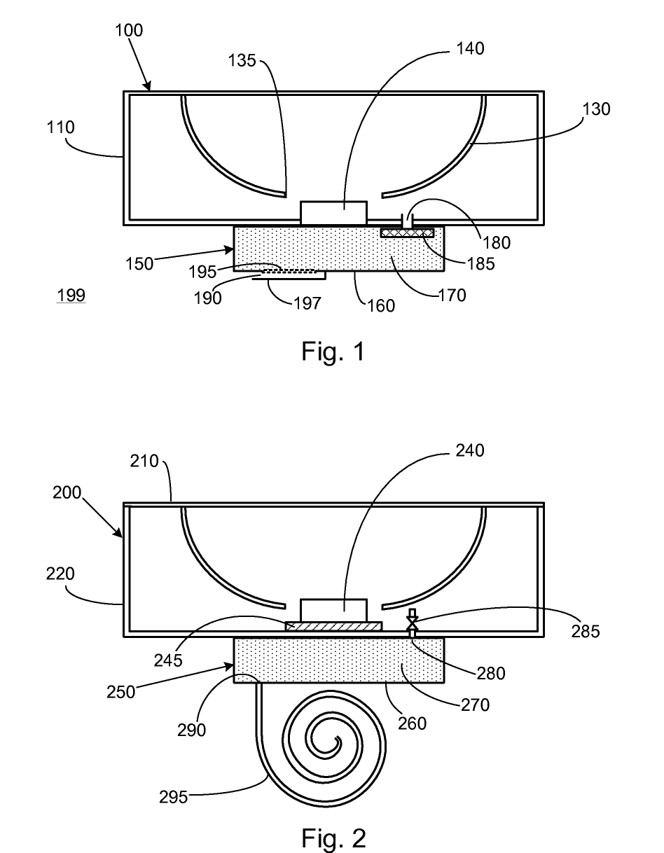

In the cross-sectional view of FIG. 1, a first embodiment of the present invention includes a solar collector 100 and a desiccant system 150. Solar collector 100, which is a general representation of solar collector, includes an enclosure 110, an optical element 130, and a receiver 140. Receiver 140 includes a photovoltaic cell and associated components critical for operation of the photovoltaic cell, such as an electrical circuit board and an electrically insulating base. Optical element 130 is depicted in FIG. 1 as a concave mirror with a central opening 135. However, optical element 130 is merely representative of one or more optics which may be utilized in a solar collector such as Fresnel lenses, convex mirrors, planar reflectors, optical prisms, parabolic troughs, and the like.

To control the moisture content of air within enclosure 110, solar collector 100 is coupled to a desiccant system 150. Desiccant system 150 includes a housing 160, a desiccant bed 170 contained in housing 160, a first orifice 180 with a moisture barrier 185, and a second orifice 190 with a moisture barrier 195. First orifice 180 couples enclosure 110 to housing 160, while second orifice 190 couples housing 160 to the external environment 199. In FIG. 1, moisture barrier 185 is depicted as a hydrophobic membrane, while moisture barrier 195 is depicted as a perforated plate. An optional splash guard 197 may be installed over second orifice 190 to prevent fluid ingress, for example from rain or when the module is being washed. Desiccant bed 170, which may occupy all of or only a portion of housing 160, may be any desiccant material such as molecular sieves, silica gel, or Montmorillonite clay. The specific type of desiccant chosen for a particular system should have an equilibrium capacity appropriate for the environmental conditions in which it will be utilized.

In the embodiment of FIG. 1, receiver 140 extends through enclosure 110 and directly contacts housing 160 so that waste heat from receiver 140 is dissipated to housing 160. Housing 160 is fabricated from a thermally conductive material such as aluminum or steel, either wholly or at least on the portion of its surface in contact with receiver 140. While heat sinks are often used in solar collectors to dissipate heat and prevent damage to photovoltaic cells, the present invention employs the excess heat for a useful purpose. Specifically, heat from receiver 140 is conducted to housing 160, which then heats desiccant bed 170. Raising the temperature of desiccant bed 170 causes desiccant bed 170 to release moisture and regenerate. Thus, the need for periodic maintenance to replace saturated desiccant material in desiccant system 150 is eliminated or reduced. Furthermore, no external energy source is required for regenerating desiccant bed 170. The desiccant system 150 of the present invention allows low moisture levels, for example less than 20% relative humidity, to be maintained.

Because highly concentrated light is transmitted to receiver 140, the temperature of desiccant bed 170 can be raised by approximately 30 to 50° C. above ambient. For example, during inoperation, such as night time or cloudy days, the desiccant bed is at ambient temperatures of 5 to 30° C. At these normal temperatures the equilibrium capacity of desiccant is high, such as greater than 20 g H₂O/100 g desiccant, and moisture can be absorbed freely. When the module becomes operational during on-sun, the receiver 140, housing 160, and desiccant bed 170 can heat up quickly to approximately 60 to 80° C. At these elevated temperatures, the equilibrium capacity of desiccant decreases to, for example, 10 g H₂O/100 g desiccant, causing the release of water vapor from the desiccant. Thus, desiccant system 150 typically releases moisture during the day and absorbs moisture during the night and during cloudy conditions, and will require little or no regular replacement of the desiccant reservoir. The amount of desiccant required to operate desiccant system 150 is also relatively small since the material is regenerated on a daily basis. Furthermore, since the desiccant system 150 is thermally coupled to receiver 140, it can be designed to heat up more quickly than the air within enclosure 110. Thus, the desiccant bed 170 releases moisture immediately before the air heats up. When the air within solar collector 100 heats up, the increased pressure within enclosure 110 pushes air through first orifice 180, through desiccant bed 170, and out second orifice 190. This process selectively pumps moisture out of the system upon initial start-up of on-sun operation.

Desiccant system 150 may be designed such that the entirety of desiccant bed 170 operates at a substantially uniform temperature. For example, the dimensions of housing 160, the conduction path from solar collector 100 to housing 160, and the layout of desiccant bed 170 within housing 160 can be optimized to achieve substantially uniform heat transfer throughout desiccant bed 170. Alternatively, portions of desiccant bed 170 can be allowed to operate at different temperatures as controlled by the heat transfer from the solar collector 100 to the desiccant bed 170. This allows the desiccant system 150 to be operated so that a colder region of the desiccant bed 170 is at a different equilibrium state than a hotter region. Thus, if the hot region is saturated and cannot accept water vapor, then the cold region will absorb that moisture before it can enter into the solar collector 100. Such a temperature differential may be achieved by, for instance, having desiccant bed 170 in contact housing 160 only in selected regions, positioning housing 160 with respect to receiver 140 so that heat transfer is non-uniform across housing 160, or insulating portions of housing 160 so that a thermal gradient is created within the walls of housing 160.

Optionally, for a desiccant system 150 that is designed such that the desiccant bed 170 operates at different temperatures, the desiccant system 150 may be designed in such a way that the component particles of desiccant bed 170 are periodically mixed or physically moved between the hotter and cooler regions within desiccant bed 170. This would prevent one portion of desiccant bed 170 from reaching saturation as a result of not being regenerated by waste heat. Such a system could be active, such as a mixing mechanism installed within the housing 160, or an access port for manual stirring of desiccant bed 170 during periodic maintenance. Alternatively, mixing of desiccant particles may rely on the movement of the solar collector 100 throughout the day. For instance, the housing 160 could be designed such that movement of a tracking system during the day causes cyclical movement of desiccant particles from the hot to the cold regions of desiccant bed 170. Such a configuration may be designed to rely on normal tracker movement, or may rely on specific tracker operations that are used only to perform this mixing, and therefore occur at night when the solar collector 100 is not in operation.

As air within solar collector 100 cyclically expands and contracts during daily operation, air is drawn into and out of solar collector 100 through first orifice 180 and second orifice 190. First orifice 180 and second orifice 190 include moisture barriers 185 and 195, respectively, to further restrict the amount of moisture entering solar collector 100. In FIG. 1, moisture barrier 185 is embodied as a liquid and vapor limiting membrane, such as a hydrophobic/oleophobic membrane, while moisture barrier 195 is depicted as a perforated plate. Although various moisture restriction devices may be incorporated, such as flow limiting valves, filters, and restrictive orifices. The combination of moisture barriers 185 and 195 should be chosen so that moisture barrier 185 has a threshold value which is more restrictive than that of moisture barrier 195. For instance, during nominal operating airflow through the system, moisture barrier 185 may have a pressure rating of 0.02 psid, while moisture barrier 195 may have a value of 0.005 psid. With such a configuration, moisture which is extracted by desiccant system 150 will preferentially be released to the environment through second orifice 190 rather than entering solar collector 100 through first orifice 180. Moisture barriers 185 and 195 may also serve to prevent particulate from entering solar collector 100.

Another advantage of the desiccant system 150 of FIG. 1 is that it may be located completely underneath solar collector 100. By being positioned underneath solar collector 100 instead of, for example, being attached to the side of solar collector 100, desiccant system 150 has no impact on the overall footprint occupied by solar collector 100. Thus, the number of solar modules installed in a given area, and the amount of energy which can be produced in that area, is preserved. Desiccant system 150 does not occupy additional surface area which could be receiving sunlight for producing energy, nor does it cause shading of adjacent modules.

Now moving to FIG. 2, an alternative embodiment of the present invention is illustrated. In this alternative embodiment, a solar collector 200 is enclosed by a front panel 210 joined to a backpan 220. A receiver 240 is coupled to a heat sink 245, which may be, for example, a block of aluminum or other metal. As described previously, receiver 240 includes a photovoltaic cell and associated components required for its operation. A desiccant system 250 coupled to solar collector 200 includes a housing 260, a desiccant bed 270, a first orifice 280 and a second orifice 290. In FIG. 2, both receiver 240 and heat sink 245 are fully contained within solar collector 200 such that heat from receiver 240 is conducted to housing 260 through heat sink 245 and backpan 220, rather than being directly conducted to housing 160 as in FIG. 1. FIG. 2 also illustrates alternative methods for moisture restriction, with first orifice 280 utilizing a flow limiting valve 285, and second orifice 290 utilizing a labyrinthine tube 295. Labyrinthine tube 295 has a diameter and length sufficient to limit diffusion of moisture into desiccant system 250. For example, labyrinthine tube 295 may have a diameter on the order of 1 mm and a length of approximately 1 meter.

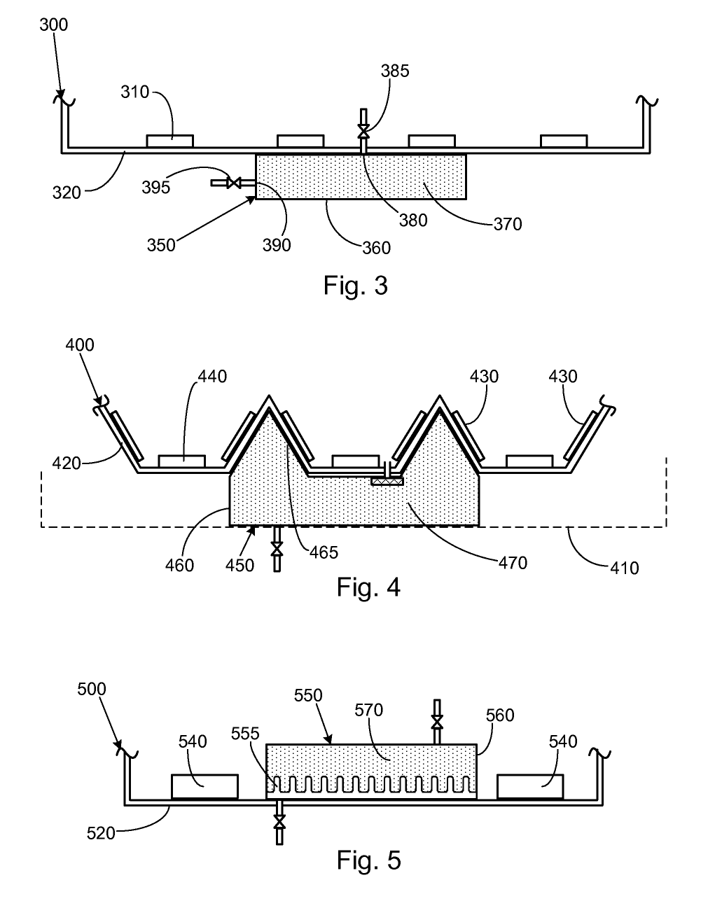

While FIGS. 1 and 2 have individual solar collectors, the present invention may also be applied to solar arrays. In the cross-sectional view of FIG. 3, a solar collector 300 with a backpan 320 contains an array of photovoltaic cells 310, each of which may have corresponding optical elements, not shown. A desiccant system 350 has a housing 360, a desiccant bed 370, a first orifice 380, and a second orifice 390. Moisture barriers 385 and 395 for first orifice 380 and second orifice 390, respectively, are depicted in this embodiment as flow limiting valves. Backpan 320 is thermally conductive, and transfers heat from the array of photovoltaic cells 310 to desiccant system 350. A single desiccant system 350 may adequately control moisture entry for the entire solar collector 300. Alternatively, more than one desiccant system 350 may be employed, depending on the volume of air contained within solar collector 300, or for example, in more humid environments requiring higher moisture absorption capacity. In another variation, more than one first orifice 380 may be installed. Such a configuration may be used, for instance, to enhance the flow of air from different sections of solar collector 300 to desiccant system 350.

In another embodiment of the present invention, FIG. 4 illustrates a solar collector 400 having a non-planar configuration. In this exemplary solar collector 400 of FIG. 4, reflective elements 430 are mounted on a thermally conductive substrate 420 having angled walls which coincide with the shape of the optics used to concentrate light upon the receiver 440. A desiccant system 450 has a housing 460 with extensions 465 shaped to mate with the non-planar shape of substrate 420. The additional surface area provided by extensions 465 of housing 460 increases the heat transfer occurring between substrate 420 and housing 460, thus improving the efficiency of heating desiccant bed 470. Note that while housing 460 is depicted with triangular extensions 465, other shapes corresponding a particular solar collector design may be employed to increase the surface area of housing 460. For instance, extensions 465 may be domed or trapezoidal in nature, and may be configured as recesses instead of extensions. Solar collector 400 may optionally include an outer enclosure 410, in which desiccant system 450 may be contained.

FIG. 5 illustrates a yet further embodiment of the present invention. In the cross-sectional view of FIG. 5, a solar collector 500 has a thermally conductive backpan 520 and an array of photovoltaic cells 540. Heat generated by photovoltaic cells 540 is conducted by backpan 520 to a desiccant system 550, which is enclosed within solar collector 500 in this embodiment. Desiccant system 550 incorporates metal fins 555, which increase the efficiency of conducting heat from housing 560 to desiccant bed 570. While fins 555 are shown as extending from the bottom of housing 560, fins 555 may extend from other surfaces of housing 560, and may be configured in other forms such as thin plates or circular rods.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention. Thus, it is intended that the present subject matter covers such modifications and variations as come within the scope of the appended claims and their equivalents.

What is claimed is:

1. A desiccant system for a solar collector, comprising:
a housing having a thermally conductive surface to conduct waste heat from said solar collector;
a desiccant bed located in said housing, wherein said housing is thermally coupled to said desiccant bed;
a first orifice coupled to said housing, wherein said first orifice comprises a first moisture barrier having a first threshold value;
a second orifice coupled to said housing, wherein said second orifice comprises a second moisture barrier having a second threshold value; and
wherein said first threshold value is more restrictive than said second threshold value to cause moisture to preferentially exit said housing through said second orifice.

2. The desiccant system of claim 1, wherein said solar collector comprises a receiver unit having a photovoltaic cell, and wherein said waste heat comprises heat dissipated from said receiver unit.

3. The desiccant system of claim 1, wherein said thermally conductive surface comprises aluminum.

4. The desiccant system of claim 1, wherein said first moisture barrier is selected from the group consisting of a hydrophobic membrane, a restrictive orifice, and a filter.

5. The desiccant system of claim 1, wherein said second moisture barrier is selected from the group consisting of a restrictive orifice, a perforated plate, a filter, and a labyrinthine tube.

6. The desiccant system of claim 1, further comprising a splash guard covering said second moisture barrier.

7. The desiccant system of claim 1, wherein said desiccant bed regenerates when heated by said waste heat from said solar collector.

8. The desiccant system of claim 1, wherein said housing further comprises fins thermally coupled to said thermally conductive surface and to said desiccant bed.

9. A solar collector system, comprising:
a solar collector comprising a photovoltaic cell and an enclosure having a first volume;
a housing comprising a second volume and a thermally conductive surface, wherein said thermally conductive surface is thermally coupled to said photovoltaic cell;
a desiccant bed located in said housing, wherein said housing is thermally coupled to said desiccant bed;
a first orifice coupling said first volume to said second volume, wherein said first orifice comprises a first moisture barrier having a first threshold value;
a second orifice coupling said second volume to an external environment, wherein said second orifice comprises a second moisture barrier having a second threshold value; and
wherein said first threshold value is more restrictive than said second threshold value to cause moisture to preferentially exit said housing through said second orifice.

10. The solar collector system of claim 9, further comprising waste heat conducted from said photovoltaic cell to said thermally conductive surface, wherein said waste heat causes said desiccant bed to regenerate.

11. The solar collector system of claim 9, further comprising waste heat conducted from said photovoltaic cell to said thermally conductive surface, and wherein a temperature differential is created within said desiccant bed when heated by said waste heat.

12. The solar collector system of claim 11, further comprising means for mixing said desiccant bed across regions of said temperature differential.

13. The solar collector system of claim 9, wherein said solar collector further comprises a heat sink coupled to said photovoltaic cell.

14. The solar collector system of claim 13, wherein said heat sink and said thermally conductive surface are both planar.

15. The solar collector system of claim 13, wherein said heat sink comprises a non-planar feature, and wherein said thermally conductive surface mates with said non-planar feature.

16. The solar collector system of claim 9, wherein said enclosure further comprises a backpan, and wherein said backpan is thermally coupled to said photovoltaic cell and to said thermally conductive surface of said housing.

17. The solar collector system of claim 9, wherein said housing is located within said enclosure of said solar energy collector.

18. The solar collector system of claim 9, wherein said housing is located externally to said enclosure of said solar energy collector.

19. The solar collector system of claim 18, wherein said housing is located underneath said enclosure.

20. The solar collector system of claim 9, wherein said solar collector further comprises air contained within said first volume, and wherein expansion of said air causes said moisture to be released from said desiccant bed to be selectively pumped out of said second orifice.

21. A method of removing moisture from within a solar collector using a desiccant system, said solar collector comprising a photovoltaic cell and an enclosure having a first volume, said desiccant system comprising a housing having a second volume and a desiccant bed located in said second volume, said method comprising:
positioning said housing in a thermally conductive relationship with said photovoltaic cell;
inserting a first orifice to fluidly couple said first volume to said second volume, wherein said first orifice comprises a first moisture barrier having a first threshold value;
inserting a second orifice to fluidly couple said second volume with an external environment, wherein said second orifice comprises a second moisture barrier having a second threshold value; and
wherein said first threshold value is more restrictive than said second threshold value to cause moisture to preferentially exit said housing through said second orifice.

22. The method of removing moisture of claim 21, wherein said step of positioning comprises positioning said housing underneath said solar collector.
